(19) United States
(12) Patent Application Publication
(10) Pub. No.: US 2009/0192065 A1
(43) Pub. Date: Jul. 30, 2009

(54) DENSE FLUID COMPOSITIONS FOR REMOVAL OF HARDENED PHOTORESIST, POST-ETCH RESIDUE AND/OR BOTTOM ANTI-REFLECTIVE COATING

(75) Inventors: Michael B. Korzenski, Danbury, CT (US); Pamela M. Visintin, North Charleston, SC (US); Thomas H. Baum, New Fairfield, CT (US); David W. Minsek, New Milford, CT (US); Chongying Xu, New Milford, CT (US)

Correspondence Address: MOORE & VAN ALLEN PLLC, P.O. BOX 13706, Research Triangle Park, NC, 27709, US

(73) Assignee: Advanced Technology Materials, Inc., Danbury, CT (US)

(21) Appl. No.: 11/917,654

(22) PCT Filed: Jun. 16, 2006
(86) PCT No.: PCT/US2006/023388

§ 371 Date: Aug. 25, 2008

Related U.S. Application Data
(60) Provisional application No. 60/691,178, filed on Jun. 16, 2005.

(51) Int. Cl. G03F 7/42

(52) U.S. Cl. 510/176; 510/175

(57) ABSTRACT

A method and composition for removing hardened photoresist, post-etch photoresist, and/or bottom anti-reflective coating from a microelectronic device is described. The composition may include a dense fluid, e.g., a supercritical fluid, and a dense fluid concentrate including a co-solvent, optionally a fluoride source, and optionally an acid. The dense fluid compositions substantially remove the contaminating residue and/or layers from the microelectronic device prior to subsequent processing, thus improving the morphology, performance, reliability and yield of the microelectronic device.

### FIELD OF THE INVENTION

The present invention relates to dense fluid compositions, e.g., supercritical fluid compositions, useful for the removal of hardened photoresist, post-etch residue and/or bottom anti-reflective coating layers from the surface of microelectronic devices, and methods of using such compositions for removal of same.

### DESCRIPTION OF THE RELATED ART

Photolithography techniques comprise the steps of coating, exposure, and development. A wafer is coated with a positive or negative photoresist substance and subsequently covered with a mask that defines patterns to be retained or removed in subsequent processes. Following the proper positioning of the mask, the mask has directed therethrough a beam of monochromatic radiation, such as ultraviolet (UV) light or deep UV (DUV) light (λ≈250 nm), to make the exposed photoresist material more or less soluble in a selected rinsing solution. The soluble photoresist material is then removed, or “developed,” thereby leaving behind a pattern identical to the mask.

Currently, there are four developed wavelengths of radiation used in the photolithographic processes for the semiconductor industry—436 nm, 365 nm, 248 nm, and 193 nm—and recent efforts have focused on 157 nm lithography processes. In theory, with each wavelength decrease, smaller features can be created on the microelectronic device chip. However, because the reflectively of the microelectronic device substrate is inversely proportional to the photolithographic wavelength, interference and unevenly exposed photoresist has limited the consistency of the critical dimensions of the microelectronic device.

For example, upon exposure to DUV radiation, it is well known that the transmissivity of photoresist combined with the high reflectivity of the substrates to the DUV wavelengths results in the reflection of the DUV radiation back into the photoresist thereby producing standing waves in the photoresist layer. The standing waves trigger further photochemical reactions in the photoresist causing an uneven exposure of the photoresist, including in masked portions not intended to be exposed to the radiation, which results in variations in linewidths, spacing and other critical dimensions.

In order to address the transmissivity and reflectivity problems, bottom anti-reflective coatings (BARCs), both inorganic and organic in nature, have been developed which are applied to substrates prior to applying the photoresist. As the photoresist is exposed to DUV radiation, the BARC absorbs a substantial amount of the DUV radiation, thereby preventing radiation reflection and standing wave exposure.

For example, organic BARCs, including, but not limited to, polysulfones, polyureas, polyurea sulfones, polyacrylates and poly(vinyl pyridine), prevent light reflection by matching the reflective index of the BARC layer with that of the photoresist layer while simultaneously absorbing radiation thereby preventing further penetration to the deeper interfaces. In contrast, inorganic BARCs, including silicon oxynitrides (SiOₓN_{y}), reduce transmissivity and reflectivity by destructive interference wherein the light reflected from the BARC-photoresist interface cancels out the light reflected from the BARC-substrate interface.

Subsequent to the development of the photoresist, back-end-of-line (BEOL) dual-damascene processing of integrated circuits is performed whereby gas-phase plasma etching is used to transfer the patterns of the developed photoresist coating to an underlying low-k layer. During pattern transfer, the reactive plasma gases react with the developed photoresist, resulting in the formation of a hardened, crosslinked polymeric material, or “crust,” on the surface of the photoresist. The reactive plasma gases also react with the sidewalls of the BARC and the features etched into the dielectric. In addition, plasma ashing leaves a post-etch residue on the substrate.

An alternative to BEOL is front-end-of-line (FEOL) processing whereby ion implantation is used to add dopant atoms to the exposed wafer layers. Ion implant-exposed photoresist is also highly cross-linked similar to plasma etched photoresist crust.

The clean removal of hardened photoresist, post-etch residue and/or BARC materials from the microelectronic device has proven to be difficult and/or costly. If not removed, the residue and/or layers may interfere with subsequent silicidation or contact formation. Typically, the layers are removed by oxidative or reductive plasma ashing or wet cleaning. However, plasma ashing, whereby the device substrate is exposed to a plasma etch, may result in damage to the dielectric material, either by changing the feature shapes and dimensions, or by an increase in the dielectric constant of the dielectric material. The latter problem is more pronounced when low-k dielectric materials, such as organosilicate glasses (OSG) or carbon-doped oxide glasses, are the underlying dielectric material. As such, it is often desirable to avoid the use of plasma ashing to remove the hardened photoresist, post-etch residue and/or BARC layers.

When a cleaner/etchant removal composition is used in BEOL applications to process surfaces having aluminum, copper or cobalt interconnected wires, it is important that the composition possess good metal compatibility, e.g., a low etch rate on the metal. Aqueous removal compositions are preferred because of the simpler disposal techniques, however, the photoresist “crust” is typically extremely insoluble in aqueous cleaners, especially cleaners that do not damage the dielectric. Often substantial quantities of co-solvents, wetting agents and/or surfactants are added to the aqueous solutions to improve the cleaning ability of the solution.

As a further and specific problem attendant the use of conventional aqueous cleaner/etchant removal compositions, the geometric scale of features in semiconductor device architectures and microelectromechanical systems (MEMS) devices continues to diminish. As critical dimensions (of high aspect ratio vias, deep trenches and other semiconductor device or precursor structure features) shrink below I micrometer, the high surface tension that is characteristic of aqueous compositions used to clean wafers prevents the penetration of the composition into the semiconductor device features. Aqueous-based etchant formulations often leave previously dissolved solutes behind in the trenches or vias upon evaporative drying, which inhibit conduction and reduce device yield. Furthermore, underlying porous low-k dielectric materials do not have sufficient mechanical strength to withstand the capillary stress of high surface tension liquids such as water, resulting in pattern collapse of the structures. Aqueous etchant formulations can also strongly alter important material properties of the low-k materials, including dielectric constant, mechanical strength, moisture uptake, coefficient of thermal expansion, and adhesion to different substrates.

Supercritical fluids (SCF) provide an alternative method for removing hardened photoresist, post-etch residue and/or BARC layers from the semiconductor device surface. SCFs diffuse rapidly, have low viscosity, near zero surface tension, and can penetrate easily into deep trenches and vias. Further, because of their low viscosity, SCFs can rapidly transport dissolved species. However, SCFs are highly non-polar and as such, many species are not adequately solubilized therein.

Recently, supercritical carbon dioxide (SCCO₂) compositions containing co-solvents have been used to enhance residue and/or layer removal, both organic and inorganic in nature, from Si/SiO₂ regions of both blanketed and patterned wafers. However, compositions containing only SCCO₂ and alkanol co-solvents have proven to be incapable of removing 100% of the species from the wafer surface.

It would therefore be a significant advance in the art to provide an improved dense fluid-based composition that overcomes the deficiencies of the prior art relating to the removal of hardened photoresist, post-etch residue and/or BARC layers from semiconductor devices.

### SUMMARY OF THE INVENTION

The present invention relates to dense fluid-based compositions useful for the removal of hardened photoresist, post-etch residue and/or BARC layers from the surface of semiconductor devices, and methods of using such compositions for removal of same.

In one aspect, the invention relates to a dense fluid concentrate comprising at least one co-solvent, optionally at least one oxidizer/radical source, optionally at least one surfactant, and optionally at least one silicon-containing layer passivating agent, wherein said concentrate is further characterized by comprising at least one of the following components (I) or (II):

(I) at least one fluoride source and optionally at least one acid; and

(II) at least one acid,

wherein said dense fluid concentrate is useful for removing hardened photoresist, post-etch residue and/or bottom anti-reflective coating (BARC) from a microelectronic device having said photoresist, residue and/or BARC thereon.

In another aspect, the present invention relates to a dense fluid composition, comprising a dense fluid and a dense fluid concentrate, wherein the dense fluid concentrate comprises at least one co-solvent, optionally at least one oxidizer/radical source, optionally at least one surfactant, and optionally at least one silicon-containing layer passivating agent, wherein said concentrate is further characterized by comprising at least one of the following components (I) or (II):

(I) at least one fluoride source and optionally at least one acid; and

(II) at least one acid,

and wherein said dense fluid concentrate is useful for removing hardened photoresist, post-etch residue and/or bottom anti-reflective coating (BARC) from a microelectronic device having said photoresist, residue and/or BARC thereon.

In yet another aspect, the present invention relates to a kit comprising, in one or more containers, one or more of the following reagents for forming a dense fluid concentrate, wherein said concentrate comprises comprising at least one co-solvent, optionally at least one oxidizer/radical source, optionally at least one surfactant, and optionally at least one silicon-containing layer passivating agent, wherein said concentrate is further characterized by comprising at least one of the following components (I) or (II):

(I) at least one fluoride source and optionally at least one acid; and

(II) at least one acid,

and wherein the kit is adapted to form dense fluid concentrates suitable for removing hardened photoresist, post-etch residue and/or bottom anti-reflective coating (BARC) from a microelectronic device having said photoresist, residue and/or BARC thereon.

In a further aspect, the present invention relates to a method of removing hardened photoresist, post-etch residue and/or bottom anti-reflective coating (BARC) from a microelectronic device having same thereon, said method comprising contacting the microelectronic device with a dense fluid concentrate for sufficient time and under sufficient contacting conditions to at least partially remove said hardened photoresist, post-etch residue and/or BARC from the microelectronic device having said photoresist, residue and/or BARC thereon, wherein the dense fluid concentrate comprises at least one co-solvent, optionally at least one oxidizer/radical source, optionally at least one surfactant, and optionally at least one silicon-containing layer passivating agent, wherein said concentrate is further characterized by comprising at least one of the following components (I) or (II):

(I) at least one fluoride source and optionally at least one acid; and

(II) at least one acid.

Another aspect of the present invention relates to a method of removing hardened photoresist, post-etch residue and/or bottom anti-reflective coating (BARC) from a microelectronic device having same thereon, said method comprising:
(a) contacting the microelectronic device with the dense fluid concentrate of claim 1, comprising component (I), for sufficient time and under sufficient contacting conditions; and

(b) contacting the same microelectronic device with the dense fluid concentrate of claim 1, comprising component (II), for sufficient time and under sufficient contacting conditions,

wherein the multi-step process at least partially removes said hardened photoresist, post-etch residue and/or BARC from the microelectronic device having same thereon.

In still another aspect, the present invention relates to a method of manufacturing a microelectronic device, said method comprising contacting the microelectronic device with a dense fluid concentrate for sufficient time to at least partially remove said hardened photoresist, post-etch residue and/or BARC from the microelectronic device having said photoresist, residue and/or BARC thereon, wherein the dense fluid concentrate comprises at least one co-solvent, optionally at least one oxidizer/radical source, optionally at least one surfactant, and optionally at least one silicon-containing layer passivating agent, wherein said concentrate is further characterized by comprising at least one of the following components (I) or (II):

(I) at least one fluoride source and optionally at least one acid; and

(II) at least one acid.

Yet another aspect of the invention relates to improved microelectronic devices, and products incorporating same, made using the methods of the invention comprising removing hardened photoresist, post-etch residue and/or BARC from a microelectronic device having said photoresist, residue and/or BARC thereon, using the methods and/or compositions described herein, and optionally, incorporating the microelectronic device into a product.

Other aspects, features and embodiments of the invention will be more fully apparent from the ensuing disclosure and appended claims.

### BRIEF DESCRIPTION OF THE DRAWINGS

FIG. 1 illustrates a micrograph of a microelectronic device having hardened photoresist, post-etch residue and/or BARC layers and the schematic of the same microelectronic device following removal of the hardened photoresist, post-etch residue and/or BARC layers using the compositions of the invention.

FIG. 2a is a scanning electron micrograph of a 193 nm VIA structure including hardened photoresist/low-k/etch-stop layer/silicon substrate before processing.

FIG. 2b is a scanning electron micrograph of the VIA structure of FIG. 1 after processing using a composition of the present invention, showing removal of the bulk photoresist layer and the VIA side-wall polymer residue.

FIG. 3a is a FESEM of a via structure having a hardened photoresist/crust/BARC layer, a SiO₂ layer, a MSQ layer, and a SiC etch stop layer (from top to bottom).

FIG. 3b is a FESEM of a via structure having a hardened photoresist/crust/BARC layer, a SiO₂ layer, a MSQ layer, and a SiC etch stop layer (from top to bottom).

FIG. 4a is a FESEM of the wafer of FIG. 3a following a wet-clean using Formulation A.

FIG. 4b is a FESEM of the wafer of FIG. 3b following a wet-clean using Formulation A.

FIG. 5a is a FESEM of the wafer of FIG. 3a following a wet-clean using Formulation B.

FIG. 5b is a FESEM of the wafer of FIG. 3b following a wet-clean using Formulation B.

FIG. 6a is a FESEM of a “no-via” structure having a hardened photoresist/crust/BARC layer, a SiO₂ layer, a MSQ layer, and a SiC etch stop layer (from top to bottom).

FIG. 6b is a FESEM of a via structure having a hardened photoresist/crust/BARC layer, a SiO₂ layer, a MSQ layer, and a SiC etch stop layer (from top to bottom).

FIG. 6c is a FESEM of a via structure having a hardened photoresist/crist/BARC layer, a SiO₂ layer, a MSQ layer, and a SiC etch stop layer (from top to bottom).

FIG. 7a is a FESEM of the wafer of FIG. 6a following a two-step dense fluid clean using formulation H in SCCO₂ followed by formulation I in SCCO₂.

FIG. 7b is a FESEM of the wafer of FIG. 6b following a two-step dense fluid clean using formulation H in SCCO₂ followed by formulation I in SCCO₂.

FIG. 7c is a FESEM of the wafer of FIG. 6c following a two-step dense fluid clean using formulation H in SCCO₂ followed by formulation I in SCCO₂.

FIG. 8b is a FESEM of the wafer of FIG. 6b following a one-step dense fluid clean using formulation I in SCCO₂.

FIG. 8c is a FESEM of the wafer of FIG. 6c following a one-step dense fluid clean using formulation I in SCCO₂.

### DETAILED DESCRIPTION OF THE INVENTION AND PREFERRED EMBODIMENTS THEREOF

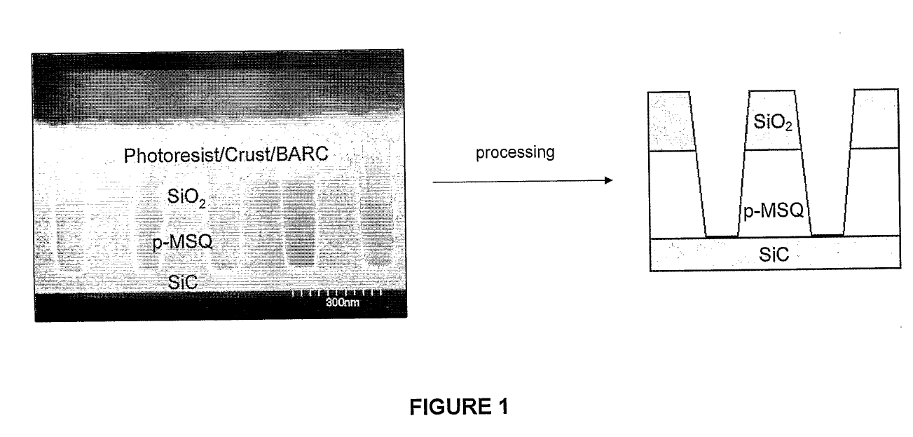

The present invention is based on the discovery of dense fluid compositions that are highly efficacious for the removal of hardened photoresist, post-etch residue and/or BARC layers from the surface of semiconductor devices, while maintaining the integrity of the underlying silicon-containing layer(s). Specifically, the present invention relates to a dense fluid composition that selectively removes hardened highly cross-linked photoresist, post-etch residue, and/or BARC layers relative to the underlying Si/SiO₂/low-k/etch stop layers, e.g., as illustrated schematically in FIG. 1.

“Hardened photoresist” as used herein includes, but is not limited to, photoresist that has been plasma etched, e.g., during BEOI, dual-damascene processing of integrated circuits, and/or ion implanted, e.g., during front-end-of-line (FEOL) processing to implant dopant species in the appropriate layers of the semiconductor wafer.

As used herein, “underlying silicon-containing” layer corresponds to the layer(s) underlying the bulk and/or the ion-implanted photoresist including: silicon; silicon oxide, silicon nitride, including gate oxides (e.g., thermally or chemically grown SiO₂); hard mask; silicon nitride; and low-k silicon-containing materials. As defined herein, “low-k silicon-containing material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), methyl silsesquioxane (MSQ), TEOS, fluorinated silicate glass (FSG), silicon dioxide, and carbon-doped oxide (CDO) glass. It is to be appreciated that the low-k dielectric materials may have varying densities and varying porosities.

“Microelectronic device,” as used herein, corresponds to resist-coated semiconductor substrates, flat panel displays, and microelectromechanical systems (MEMS), manufactured for use in microelectronic, integrated circuit, or computer chip applications. It is to be understood that the term “microelectronic device” is not meant to be limiting in any way and includes any substrate that will eventually become a microelectronic device or microelectronic assembly.

“Post-etch residue” as used herein corresponds to material remaining following gas-phase plasma etching processes, e.g., BEOL dual damascene processing. The post-etch residue may be organic, organometallic, organosilicic, or inorganic in nature, for example, silicon-containing material, carbon-based organic material, and etch gas residue including, but not limited to, oxygen and fluorine.

As used herein, “about” is intended to correspond to ±5% of the stated value.

As used herein, “suitability” for removing hardened photoresist, post-etch residue and/or BARC from the surface of a microelectronic device having such material(s) thereon corresponds to at least partial removal of said materials from the microelectronic device. Preferably, at least 90% of the materials are removed from the microelectronic device using the compositions of the invention, more preferably, at least 95% of the materials are removed, and most preferably at least 99% of the materials, are removed.

“Dense fluid,” as used herein, corresponds to a supercritical fluid or a subcritical fluid. The term “supercritical fluid” (SCF) is used herein to denote a material which is under conditions of not lower than a critical temperature, T_{c}, and not less than a critical pressure, P_{c}, in a pressure-temperature diagram of an intended compound. The preferred supercritical fluid employed in the present invention is CO₂, which may be used alone or in an admixture with another additive such as Ar, NH₃, N₂, CH₄, C₂H₄, CHF₃, C₂H₆, n-C₃H₈, H₂O, N₂O and the like. The term “subcritical fluid” describes a solvent in the subcritical state, i.e., below the critical temperature and/or below the critical pressure associated with that particular solvent. Preferably, the subcritical fluid is a high pressure liquid of varying density. Specific reference to supercritical-based compositions hereinafter in the broad description of the invention is meant to provide an illustrative example of the present invention and is not meant to limit same in any way, i.e., the described compositions may instead be subcritical in nature.

As used herein, “concentrate” corresponds to a liquid composition that may be used to remove hardened photoresist, post-etch residue and/or BARC layers, either in said concentrated form or as a diluted composition, e.g., diluted with a solvent and/or a dense fluid.

Importantly, the dense fluid compositions of the present invention must possess good metal compatibility, e.g., a low etch rate on the metal. Metals of interest include, but are not limited to, copper, tungsten, cobalt, aluminum, tantalum, titanium and ruthenium.

Because of its readily manufactured character and its lack of toxicity and negligible environmental effects, supercritical carbon dioxide (SCCO₂) is a preferred dense fluid in the broad practice of the present invention, although the invention may be practiced with any suitable SCF or subcritical species, with the choice of a particular dense fluid depending on the specific application involved. Other preferred dense fluid species useful in the practice of the invention include oxygen, argon, krypton, xenon, and ammonia. Specific reference to SCCO₂ hereinafter in the broad description of the invention is meant to provide an illustrative example of the present invention and is not meant to limit same in any way.

SCCO₂ is an attractive reagent for removal of semiconductor process contaminants, since SCCO₂ has the characteristics of both a liquid and a gas. Like a gas, it diffuses rapidly, has low viscosity, near-zero surface tension, and penetrates easily into deep trenches and vias. Like a liquid, it has bulk flow capability as a “wash” medium. SCCO₂ also has the advantage of being recyclable, thus minimizing waste storage and disposal requirements.

Ostensibly, SCCO₂ is an attractive reagent for the removal of post-etch residue and/or unwanted hardened photoresist or BARC layers, because all are non-polar. However, neat SCCO₂ has not proven to be an effective medium for solubilizing non-polar residue and/or layers. Furthermore, the addition of a polar co-solvent, e.g., alcohols, to the SCCO₂ has not substantially improved the solubility of the residue and/or layers in the SCCO₂ composition. Accordingly, there is a continuing need to modify the SCCO₂ composition to enhance the removal of hardened photoresist, post-etch residue and/or BARC layers from the semiconductor device surface.

The presence of fluoride ions from various sources, e.g., ammonium fluoride, triethylamine trihydrofluoride, hydrofluoric acid, etc., is known to increase the etch rates of aqueous and non-aqueous solutions towards silicon oxide dielectric materials. Therefore, it is expected that a controlled amount of a fluoride source in a dense fluid composition should effectively clean/remove oxides and oxide-containing residues, e.g., inorganic BARC layers. Generally, fluoride sources exhibit very low solubilities in SCCO₂. Therefore, the present invention includes the addition of co-solvent(s) to increase the solubility of fluoride-source(s) in the SCCO₂ composition.

The present invention overcomes the disadvantages associated with the non-polarity of SCCO₂ and other dense fluids by appropriate formulation of dense fluid removal compositions with additives as hereinafter more fully described, and the accompanying discovery that removing hardened photoresist, post-etch residue and/or BARC layers from a microelectronic device with a dense fluid removal medium is highly effective and achieves substantially damage-free, residue-free and selective removal of the residue and/or layers from the substrate, e.g., a patterned ion implanted semiconductor device wafer, having same thereon.

Compositions of the invention may be embodied in a wide variety of specific formulations, as hereinafter more fully described.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.01 weight percent, based on the total weight of the composition in which such components are employed.

In one aspect, the invention relates to a dense fluid removal concentrate for combination with a dense fluid to form a dense fluid removal composition useful in removing hardened photoresist, post-etch residue and/or BARC layers from a semiconductor device. The concentrate of the present invention includes at least one co-solvent, optionally at least one fluoride source, optionally at least one oxidizer/radical source, optionally at least one surfactant, optionally at least one acid, and optionally at least one silicon-containing layer passivating agent, present in the following ranges, based on the total weight of the composition:

| component of | % by weight |
|---|---|
| co-solvent(s) | about 0.01% to about 99.9% |
| fluoride source(s) | 0% to about 5.0% |
| oxidizer/radical source(s) | 0% to about 15.0% |
| surfactant(s) | 0% to about 5.0% |
| acid(s) | 0% to about 99% |
| silicon-containing layer | 0 to about 10% |
| passivating agent(s) | |

The amount of dense fluid removal concentrate that may be combined with dense fluid to form a dense fluid removal composition is in a range from about 0.01 wt. % to about 25 wt. %, preferably about 1 wt. % to about 20 wt. %, and even more preferably about 5 wt. %, based on the total weight of the composition. Importantly, the dense fluid removal concentrate may be at least partially dissolved and/or suspended within the dense fluid of the dense fluid removal composition. Subsequent to combination with the dense fluid, the components of the concentrate may be present in the following ranges, based on the total weight of the composition:

| component of | % by weight |
|---|---|
| co-solvent(s) | about 0.0001% to about 25% |
| fluoride source(s) | 0% to about 2% |
| oxidizer/radical source(s) | 0% to about 4% |
| surfactant(s) | 0% to about 2% |
| acid(s) | 0% to about 25% |
| silicon-containing layer | 0 to about 3% |
| passivating agent(s) | |

In the broad practice of the invention, the dense fluid removal concentrate may comprise, consist of, or consist essentially of at least one co-solvent, optionally at least one fluoride source, optionally at least one oxidizer/radical source, optionally at least one surfactant, optionally at least one acid, and optionally at least one silicon-containing layer passivating agent. In general, the specific proportions and amounts of co-solvent(s), optional fluoride source(s), optional oxidizer/radical source(s), optional surfactant(s), optional acid(s) and optional silicon-containing passivating agent(s) in relation to each other may be suitably varied to provide the desired removal action of the dense fluid composition for the hardened photoresist, post-etch residue, BARC layer species and/or processing equipment, as readily determinable within the skill of the art without undue effort. Similarly, in the broad practice of the invention, the dense fluid removal composition may comprise, consist of, or consist essentially of dense fluid and dense fluid concentrate.

Another preferred embodiment of the present invention relates to a concentrate which includes the following components present in the following ranges, based on the total weight of the composition:

| component of | % by weight |
|---|---|
| co-solvent(s) | about 50% to about 99.9% |
| fluoride source(s) | about 0.01% to about 2.0% |
| oxidizer/radical source(s) | 0% to about 10.0% |
| surfactant(s) | 0% to about 5.0% |
| acid(s) | 0% to about 99% |
| silicon-containing layer | 0 to about 2% |
| passivating agent(s) | |

Subsequent to combination with the dense fluid, the components of the concentrate may be present in the following ranges, based on the total weight of the composition:

| component of | % by weight |
|---|---|
| co-solvent(s) | about 0.0001% to about 25% |
| fluoride source(s) | about 0.0001% to about 1% |
| oxidizer/radical source(s) | 0% to about 4% |
| surfactant(s) | 0% to about 2% |
| acid(s) | 0% to about 25% |
| silicon-containing layer | 0 to about 3% |
| passivating agent(s) | |

In another preferred embodiment of the present invention, the concentrate includes the following components present in the following ranges, based on the total weight of the composition:

| component of | % by weight |
|---|---|
| co-solvent(s) | about 1% to about 50% |
| fluoride source(s) | about 0.01% to about 5.0% |
| oxidizer/radical source(s) | 0% to about 10.0% |
| surfactant(s) | 0% to about 5.0% |
| acid(s) | about 1% to about 99% |
| silicon-containing layer | 0 to about 2% |
| passivating agent(s) | |

Subsequent to combination with the dense fluid, the components of the concentrate may be present in the following ranges, based on the total weight of the composition:

| component of | % by weight |
|---|---|
| co-solvent(s) | about 0.0001% to about 25% |
| fluoride source(s) | about 0.0001% to about 1% |
| oxidizer/radical source(s) | 0% to about 4% |
| surfactant(s) | 0% to about 2% |
| acid(s) | about 0.1% to about 25% |
| silicon-containing layer | 0 to about 3% |
| passivating agent(s) | |

In yet another preferred embodiment of the present invention, the concentrate includes the following components present in the following ranges, based on the total weight of the composition:

| component of | % by weight |
|---|---|
| co-solvent(s) | about 1% to about 50% |
| fluoride source(s) | 0% to about 5.0% |
| oxidizer/radical source(s) | 0% to about 10.0% |
| surfactant(s) | 0% to about 5.0% |
| acid(s) | about 55% to about 99% |
| silicon-containing layer | 0 to about 2% |
| passivating agent(s) | |

Subsequent to combination with the dense fluid, the components of the concentrate may be present in the following ranges, based on the total weight of the composition:

| component of | % by weight |
|---|---|
| co-solvent(s) | about 0.0001% to about 25% |
| fluoride source(s) | 0% to about 1% |
| oxidizer/radical source(s) | 0% to about 4% |
| surfactant(s) | 0% to about 2% |
| acid(s) | about 10% to about 25% |
| silicon-containing layer | 0 to about 3% |
| passivating agent(s) | |

The fluoride source aids in residue removal by chemically reacting with the silicon-containing residue, reducing the size of the residue material and aiding in the removal of same. Fluoride sources usefully employed in the broad practice of the invention include, without limitation, hydrogen fluoride (HF), ammonium fluoride (NH₄F), alkyl hydrogen fluoride (NRH₃F), dialkylammonium hydrogen fluoride (NR₂H₂F), trialkylammonium hydrogen fluoride (NR₃HF), trialkylammonium trihydrogen fluoride (NR₃(3HF)), tetraalkylammonium fluoride (NR₄F), pyridine-HF complex, triethanolamine-HF complex, ethylene glycol:HF (anhydrous), propylene glycol:HF (anhydrous), and xenon difluoride (XeF₂), wherein each R in the aforementioned R-substituted species is independently selected from straight-chained and branched C₁-C₈ alkyl (e.g. methyl, ethyl, propyl, butyl, pentyl, hexyl, heptyl and octyl) and substituted and unsubstituted C₆-C₁₀ aryl (e.g., phenyl, etc.). In addition, salts of bifluorides may be used, including ammonium bifluoride ((NH₄)HF₂) and tetraalkylammonium bifluorides ((R)₄NHF₂, where R is methyl, ethyl, propyl, butyl, phenyl, benzyl, or fluorinated C₁-C₄ alkyl groups. Triethylamine trihydrogen fluoride is a preferred fluoride source due to its mild fluorination properties and favorable solubility in SCCO₂. It is noted that ethylene glycol:HF (anhydrous), propylene glycol:HF (anhydrous) may be prepared by bubbling HF gas into the respective glycol.

The inclusion of the co-solvent with dense fluid serves to increase the solubility of the concentrate for hardened photoresist, post-etch residue and/or BARC constituent species, e.g., SiOₓN_{y}, polysulfones, polyureas, acrylates, poly(methyl methacrylate) (PMMA), etc. Co-solvent species useful in the cleaning compositions of the invention may be of any suitable type, including non-polar and/or polar species such as alcohols, amides, ketones, esters, etc. Illustrative species include, but are not limited to, methanol, ethanol, isopropanol, and higher alcohols, N-alkylpyrrolidinones or N-arylpyrrolidinones, such as N-methyl-, N-octyl-, or N-phenyl-pyrrolidinones, dimethylsulfoxide (DMSO), sulfolane, catechol, ethyl lactate, acetone, ethyl acetate, butyl carbitol, monoethanolamine, butyrol lactone, diglycol amine, γ-butyrolactone, butylene carbonate, propylene carbonate, tetrahydrofuran (THF), N-methylpyrrolidinone (NMP), dimethylformamide (DMF), methyl formate, diethyl ether, ethyl benzoate, acetonitrile, ethylene glycol, propylene glycol, acetic acid, dioxane, methyl carbitol, butyl carbitol, monoethanolamine, pyridine, toluene, decane, hexane, hexanes, xylenes, odorless mineral spirits (petroleum naphtha), mineral spirits (hydrotreated heavy naphtha), cyclohexane, 1H,1H,9H-perfluoro-1-nonanol, perfluoro-1,2-dimethylcyclobutane, perfluoro-1,2-dimethylcyclohexane, and perfluorohexane(s), and mixtures thereof. Methanol, pentanol, DMSO, NMP, sulfolane, and ethyl acetate are especially preferred.

The oxidizer/radical source can serve to react with the cross-linked polymeric chemical bonds in the BARC layer and/or the hardened crust on the surface of the photoresist, aiding in the removal of the layer by the dense fluid removal concentrate. Oxidizers/radical sources usefully employed in the broad practice of the invention include, without limitation, alkyl peroxide (RO—OR), hydroperoxide (HO—OR), hydrogen peroxide, alkyl peracid (R-(C=O)—O—OH), alkoyl peroxide (R-(C=O)—O—O—(C=O)-R), alkyl hypochlorite (RO-Cl), wherein each R in the aforementioned R-substituted species is independently selected from straight chained and branced C₁-C₈ alkyl and substituted and unsubstituted C₆-C₁₀ aryl, sulfur trioxide (SO₃), nitric oxide (NO₂ or NO), ozone, 4,4-azobis(4-cyanovaleric acid), 1,1′-azobis(cyclohexanecarbonitrile), 2,2′-azobisisobutyronitrile (AIBN), tris(trimethylsilyl)silane (TTMSS), tetraethylthiuram disulfide, benzoyl peroxide, ethyl peroxydicarbonate, tert-butyl peracetate, di-tert-butyl peroxide, 2,4-pentanedione peroxide, 2-butanone peroxide, di-tert-amyl peroxide, tert-butylperoxy isopropyl carbonate, diacylperoxides, peroxydicarbonates, dialkyl peroxydicarbonates, acetyl peroxide, lauryl peroxide, cumene hydroperoxide, dicumyl peroxide, tert-butyl hydroperoxide, bis(trifluoroacetyl) peroxide, bis(2,3,3,3-tetrafluoro-2-(heptafluoropropoxy)-1-oxopropyl) peroxide, diacetyl peroxide, cyclohexanone peroxide, aryl halides, acyl halides, alkyl halides (e.g., ethylbromide and ethyliodide), halogens (e.g., chlorine and bromine), 2,2,6,6-tetramethylpiperidinoxyl (TEMPO), a source of ultraviolet (UV) light, a metal (e.g., copper, magnesium, zinc), or mixtures thereof.

The surfactants contemplated in the dense fluid removal concentrate of the present invention may include nonionic surfactants, such as fluoroalkyl surfactants, ethoxylated fluorosurfactants, polyethylene glycols, polypropylene glycols, polyethylene or polypropylene glycol ethers, carboxylic acid salts, dodecylbenzenesulfonic acid or salts thereof, polyacrylate polymers, dinonylphenyl polyoxyethylene, silicone or modified silicone polymers, acetylenic diols or modified acetylenic diols, and alkylammonium or modified alkylammonium salts, as well as combinations comprising at least one of the foregoing.

Alternatively, the surfactants may include anionic surfactants, or a mixture of anionic and non-ionic surfactants. Anionic surfactants contemplated in the dense fluid composition of the present invention include, but are not limited to, fluorosurfactants such as ZONYL® UR and ZONYL® FS-62 (DuPont Canada Inc., Mississauga, Ontario, Canada), sodium alkyl sulfates, ammonium alkyl sulfates, alkyl (C₁₀-C₁₈) carboxylic acid ammonium salts, sodium sulfosuccinates and esters thereof, e.g., dioctyl sodium sulfosuccinate, and alkyl (C₁₀-C₁₈) sulfonic acid sodium salts.

The acids of the invention may be included to break/solubilize the cross-linked polymeric bonds of the photoresist. Acids contemplated herein include, but are not limited to, oxalic acid, succinic acid, citric acid, lactic acid, acetic acid, trifluoroacetic acid, formic acid, fumaric acid, acrylic acid, malonic acid, maleic acid, malic acid, L-tartaric acid, methyl sulfonic acid, trifluoromethanesulfonic acid, iodic acid, mercaptoacetic acid, thioacetic acid, glycolic acid, sulfuric acid, nitric acid, pyrrole, isoxazole, propynoic acid, pyrazine, pyruvic acid, acetoacetic acid, 1,1,1,5,5,5-hexafluoro-2,4-pentanedione (hfacH), 1,1,1-trifluoro-2,4-pentanedione (tfacH), acetylacetone (acacH), or mixtures thereof.

In addition, a silicon-containing layer passivating agent may be added to reduce the chemical attack of the silicon-containing layer(s). Silicon-containing layer passivating agents contemplated for use include, but are not limited to, hexamethyldisilazane (HMDS), alkoxysilanes including (RO)₃SiX, (RO)₂SiX₂, (RO)SiX₃, where X=methyl, ethyl, propyl, etc., and RO=methoxy, ethoxy, propoxy, etc., alkylhalosilanes of the nature (R)₃SiX, (R)₂SiX₂, (R)SiX₃, where X=F, Cl, Br or I, and R=methyl, ethyl, propyl, etc., or combinations thereof. In addition, acids and/or inacids can be usefully employed for such purpose. For example, the passivating agent may include boric acid, triethyl borate, 3-hydroxy-2-naphthoic acid, malonic acid, iminodiacetic acid, and triethanolamine. In a preferred embodiment, the passivating agent includes boric acid. In one embodiment, an alkoxysilane may be included for repair purposes.

Importantly, the dense fluid removal concentrate of the present invention is preferably substantially devoid of water and may be substantially devoid of carbonate species, although residual quantities of water may be present in the removal concentrate due to the presence of water in the individual components of the concentrate. As defined herein, “substantially devoid” corresponds to less than about 1 wt. %, more preferably less than 0.5 wt. %, and most preferably less than 0.1 wt. % of the concentrate, based on the total weight of said concentrate.

In general, the specific proportions and amounts of dense fluid(s) and dense fluid removal concentrate, including co-solvent(s), optional fluoride source(s), optional surfactant(s), optional oxidizer/radical source(s), optional acid(s), and optional silicon-containing layer passivating agent(s), in relation to each other may be suitably varied to provide the desired solubilizing (solvating) action of the dense fluid removal composition for the specific hardened photoresist, post-etch residue and/or BARC layers to be cleaned from the device substrate. Such specific proportions and amounts are readily determinable by simple experiment within the skill of the art without undue effort.

It is to be understood that the phrase “removing hardened photoresist, post-etch residue and/or bottom anti-reflective coating from a microelectronic device” is not meant to be limiting in any way and includes the removal of hardened photoresist, post-etch residue and/or BARC material from any substrate that will eventually become a microelectronic device.

The removal efficiency of the dense fluid removal composition may be enhanced by use of elevated temperature conditions in the contacting of the hardened photoresist, post-etch residue and/or BARC layers to be removed with the dense fluid-based removal composition.

The dense fluid removal compositions of the invention may optionally be formulated with additional components to further enhance the removal capability of the composition, or to otherwise improve the character of the composition. Accordingly, the composition may be formulated with stabilizers, chelating agents, complexing agents, etc. In another embodiment, the composition is devoid of chelating agent.

In one embodiment, the dense fluid removal composition of the invention includes SCCO₂, co-solvent(s) and fluoride source(s). In another embodiment, the dense fluid removal composition of the invention includes SCCO₂, co-solvent(s), and oxidizer/radical source(s). In still another embodiment, the dense fluid removal composition of the invention includes SCCO₂, co-solvent(s), fluoride source(s) and acid(s). In yet another embodiment, the dense fluid removal composition of the invention includes SCCO₂, co-solvent(s), and acid(s). In yet another embodiment, the dense fluid removal composition of the invention includes SCCO₂, co-solvent(s) and silicon-containing layer passivating agent. In still another embodiment, the dense fluid removal composition includes SCCO₂, co-solvent(s), fluoride source(s) and silicon-containing layer passivating agent. In a further embodiment, the dense fluid removal composition includes SCCO₂, co-solvent(s), fluoride source(s), oxidizer/radical source(s) and silicon-containing layer passivating agent.

In another preferred embodiment, the dense fluid removal composition of the present invention includes at least one dense fluid, the dense fluid removal concentrate, and residue material, wherein the residue material includes hardened photoresist, post-etch residue and/or BARC residue material, wherein the dense fluid removal concentrate includes at least one co-solvent, optionally at least one fluoride source, optionally at least one oxidizer/radical source, optionally at least one surfactant, optionally at least one acid, and optionally at least one silicon-containing layer passivating agent. Importantly, the residue material may be dissolved and/or suspended in the liquid removal composition of the invention.

Preferably the dense fluid compositions of the invention comprise less than 15% by weight of concentrate (other than the dense fluid), more preferably less than 10% by weight. Accordingly, in another embodiment, the dense fluid compositions of the present invention having less than 15% by weight of concentrate are capable of removing at least 90% of the hardened photoresist, post-etch residue and/or BARC from a microelectronic device having said photoresist, residue and/or BARC thereon.

The dense fluid removal compositions of the invention are easily formulated by addition of the concentrate or individual components of the concentrate, i.e., co-solvent(s), fluoride source(s), optional oxidizers(s), optional surfactant(s), optional acid(s), and optional silicon-containing layer passivating agent(s), to a dense fluid solvent. The co-solvent(s), fluoride source(s), optional oxidizers(s), optional surfactant(s), optional acid(s) and optional silicon-containing layer passivating agent(s) may be readily formulated as single-package formulations or multi-part formulations that are mixed at the point of use. The individual parts of the multi-part formulation may be mixed at the tool or in a storage tank upstream of the tool. The concentrations of the single-package formulations or the individual parts of the multi-part formulation may be widely varied in specific multiples, i.e., more dilute or more concentrated, in the broad practice of the invention, and it will be appreciated that the dense fluid removal compositions of the invention can variously and alternatively comprise, consist or consist essentially of any combination of ingredients consistent with the disclosure herein.

Accordingly, another aspect of the invention relates to a kit including, in one or more containers, one or more components of the dense fluid removal concentrate adapted to form the compositions of the invention. Preferably, the kit includes, in one or more containers, at least one co-solvent, at least one fluoride source, optionally at least one oxidizer, optionally at least one surfactant, optionally at least one acid, and optionally at least one silicon-containing layer passivating agent, for combining with the dense fluid at the fab. According to another embodiment, the kit includes, in one or more containers, at least one fluoride source, optionally at least one oxidizer, optionally at least one surfactant, optionally at least one acid, and optionally at least one silicon-containing layer passivating agent, for combining with the at least one co-solvent and the dense fluid at the fab. According to another embodiment, the kit includes, in one or more containers, at least one acid, at least one co-solvent, optionally at least one oxidizer, optionally at least one surfactant, optionally at least one fluoride source, and optionally at least one silicon-containing layer passivating agent, for combining with the dense fluid at the fab. The containers of the kit should be chemically rated to store and dispense the component(s) contained therein. For example, the containers of the kit may be NOWPak® containers (Advanced Technology Materials, Inc., Danbury, Conn., USA).

In another aspect, the invention relates to methods of removal of hardened photoresist, post-etch residue and/or BARC layers, e.g., silicon-containing and/or organic materials, from a semiconductor device using the dense fluid removal concentrates described herein. For example, trench and VIA structures on the patterned wafers may be cleaned while maintaining the structural integrity of the underlying silicon-containing layers.

In removal application, the dense fluid concentrate, or diluted composition including said concentrate, may be applied in any suitable manner to the microelectronic device having hardened photoresist, post-etch residue and/or BARC material thereon, e.g., by spraying the concentrate or composition on the surface of the device, by dipping (in a volume of the concentrate or composition) of the device including the material, by contacting the device with another material, e.g., a pad, or fibrous sorbent applicator element, that is saturated with the concentrate or composition, by contacting the device including the material with a circulating concentrate or composition, or by any other suitable means, manner or technique, by which the dense fluid concentrate or composition are brought into contact with the material on the microelectronic device. The removal application may be static or dynamic, as readily determined by one skilled in the art.

In use of the concentrates or compositions of the invention for removing hardened photoresist, post-etch residue and/or BARC material from microelectronic device surfaces having same thereon, the dense fluid concentrate or composition typically are contacted with the device surface for a time of from about 1 to about 60 minutes, preferably about 15 to about 45 minutes. Preferably, temperature is in a range of from about 20° C. to about 80° C., preferably about 30° C. to about 70° C. Such contacting times and temperatures are illustrative, and any other suitable time and temperature conditions may be employed that are efficacious to at least partially remove the material from the device surface, within the broad practice of the invention. As defined herein, “at least partial removal” corresponds to at least 90% removal of the material, preferably at least 95% removal. Most preferably, at least 99% of said material is removed using the concentrates or compositions of the present invention.

Following the achievement of the desired passivation and cleaning action, the microelectronic device may be thoroughly rinsed to remove any residual chemical additives.

In yet another aspect, the invention relates to methods of removal of hardened photoresist, post-etch residue and/or BARC layers, e.g., silicon-containing and/or organic materials, from a semiconductor device using the dense fluid removal compositions described herein. For example, trench and VIA structures on the patterned wafers may be cleaned while maintaining the structural integrity of the underlying silicon-containing layers.

The dense fluid removal compositions of the present invention overcome the disadvantages of the prior art removal techniques by minimizing the volume of chemical reagents needed, thus reducing the quantity of waste, while simultaneously providing a composition and method having recyclable constituents, e.g., the SCFs. Furthermore, the dense fluid removal compositions of the invention effectively remove hardened photoresist, post-etch residue and/or BARC without substantially over-etching the underlying silicon-containing layer(s) and metallic interconnect materials.

The dense fluid removal compositions of the invention are readily formulated by static or dynamic mixing at the appropriate temperature and pressure.

Once formulated, such dense fluid removal compositions may be applied to the microelectronic device surface for contacting with the hardened photoresist, residue and/or BARC thereon, at suitable elevated pressures, e.g., in a pressurized contacting chamber to which the dense fluid composition is supplied at suitable volumetric rate and amount to effect the desired contacting operation, for at least partial removal of the photoresist, residue and/or BARC from the microelectronic device surface. The chamber may be a batch or single wafer chamber, for continuous, pulsed, dynamic, or static cleaning.

The appropriate dense fluid composition can be employed to contact a device surface having residue and/or layered contaminants (e.g., hardened photoresist, BARC layers, post-etch residue), thereon at a pressure in a range of from about 800 to about 10,000 psi, preferably in a range of from about 2000 to about 4500 psi, for sufficient time to effect the desired removal of the particulate matter, e.g., for a contacting time in a range of from about 5 minutes to about 30 minutes and a temperature of from about 20° C. to about 150° C., preferably in a range of from about 35° C. to about 75° C., although greater or lesser contacting durations and temperatures may be advantageously employed in the broad practice of the present invention, where warranted. In a preferred embodiment, the contacting temperature is in the range of from about 50° C. to about 70° C., and the pressure is about 3000 psi.

The removal process in a particularly preferred embodiment includes sequential processing steps including dynamic flow of the dense fluid composition over the contaminated device surface, followed by a static soak of the device wafer in the dense fluid composition, with the respective dynamic flow and static soak steps being carried out alternatingly and repetitively, in a cycle of such alternating steps.

A “dynamic” contacting mode involves continuous flow of the composition over the device surface, to maximize the mass transfer gradient and effect complete removal of the particulate material from the surface. A “static soak” contacting mode involves contacting the device surface with a static volume of the composition, and maintaining contact therewith for a continued (soaking) period of time.

For example, the dynamic flow/static soak steps may be carried out for successive cycles in the aforementioned illustrative embodiment, as including a sequence of 5 min-10 min dynamic flow, 2.5 min-5 min static soak, e.g., at about 3000 psi, and 2.5 min-5 min dynamic flow.

It is to be appreciated by one skilled in the art that the contacting mode can be exclusively dynamic, exclusively static or any combination of dynamic and static steps needed to effectuate at least partial removal of the hardened photoresist, post-etch residue and/or BARC layers from the microelectronic device.

In addition, the removal process may be a one-step or a multi-step process. For example, the removal process may be exclusively carried out with a specific dense fluid removal composition or alternatively may include the exposure of the microelectronic device to be cleaned to a first dense fluid removal composition, followed by exposure of said device to a second dense fluid removal composition, wherein the first and second dense fluid removal compositions may or may not include the same components in the same concentrations. For example, in one embodiment of the present invention, the first dense fluid composition includes a fluoride source while the second dense fluid composition does not and instead includes an acid.

Following the contacting of the dense fluid composition with the microelectronic device, the device thereafter preferably is washed with copious amounts of dense fluid/methanol solution in a first washing step, to remove any residual precipitated chemical additives from the region of the device surface in which removal has been effected, and finally with copious amounts of pure dense fluid, in a second washing step, to remove any residual methanol and/or precipitated chemical additives from the device surface. Preferably, the dense fluid used for washing is SCCO₂. For example, the first washing step can be a three volume SCCO₂/methanol (20%) solution and the second washing step can be a three volume pure SCCO₂ rinse.

It will be appreciated that specific contacting conditions for the dense fluid compositions of the invention are readily determinable within the skill of the art, based on the disclosure herein, and that the specific proportions of ingredients and concentrations of ingredients in the dense fluid compositions of the invention may be widely varied while achieving desired removal of the particulate material from the microelectronic device.

Yet another aspect of the invention relates to the improved microelectronic devices made according to the methods of the invention and to products containing such microelectronic devices.

A still further aspect of the invention relates to methods of manufacturing an article comprising a microelectronic device, said method comprising contacting the microelectronic device with an dense fluid removal composition for sufficient time to at least partially remove hardened photoresist, post-etch residue and/or BARC from the microelectronic device having said materials thereon, and incorporating said microelectronic device into said article, wherein dense fluid removal composition includes dense carbon dioxide and a dense fluid concentration, wherein the concentrate includes at least one co-solvent, at least fluoride source, optionally at least oxidizer, optionally at least one surfactant, optionally at least one acid, and optionally at least one silicon-containing layer passivating agent.

In addition, it is contemplated herein that the concentrates described herein may be diluted with a solvent such as water in a ratio of about 1:1 to about 100:1 and used as a post-chemical mechanical polishing (CMP) composition to remove post-CMP residue including, but not limited to, particles from the polishing slurry, carbon-rich particles, polishing pad particles, brush deloading particles, equipment materials of construction particles, copper, copper oxides, and any other materials that are the by-products of the CMP process.

The features and advantages of the invention are more fully shown by the illustrative example discussed below.

### EXAMPLE 1

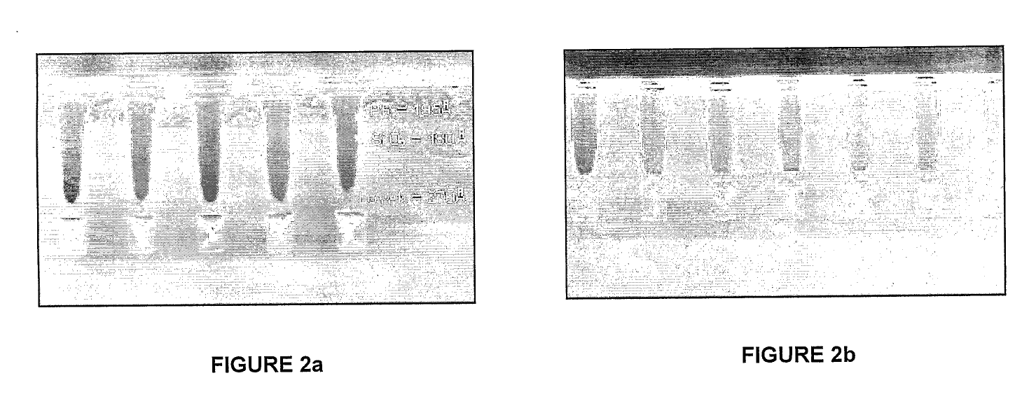

The sample wafers examined in this study were patterned silicon wafers including a hardened photoresist layer (not highly cross-linked), a low-k dielectric layer and an etch stop layer. Various chemical additives, as described herein, were added to the dense fluid composition and removal efficiency of said composition evaluated. The dense fluid composition included SCCO₂, 6 wt. % alcohol, 0.04 wt. % fluoride source, and 0.003 wt. % passivator agent. The temperature of the dense fluid composition was maintained at 50° C. throughout the removal experiments. The removal conditions included the three-step dynamic flow/static soak steps described hereinabove. Following removal, the wafers were thoroughly rinsed first with copious amounts of SCCO₂/methanol and then with copious amounts of pure SCCO₂ in order to remove any residual solvent and/or precipitated chemical additives. The results are shown in FIGS. 2a-2b, as described hereinbelow.

FIG. 2a is a scanning electron micrograph of the wafer showing the photoresist, a SiO₂ hard cap, and a low-k dielectric layer and an etch stop layer on a silicon wafer surface.

FIG. 2b is the same wafer cleaned with the SCCO₂/co-solvent/fluoride source/low-k passivator solution as taught herein. The results show that the photoresist crust was completely removed without damaging the dielectric low-k material or hard cap layer. Mercury probe measurements showed an average decrease in k-value of 3-7% due to the removal of any residual water in the low-k material. Etch rates as low as 0.5 nm/min of the low-k material were observed.

The above-described micrographs thus evidence the efficacy of dense fluid compositions in accordance with the invention, for removal of hardened photoresist from microelectronic device surfaces.

### EXAMPLE 2

Dense fluid removal concentrates A-G were prepared as followed, wherein each component is present in weight percent, based on the total weight of the composition.

Formulation A

| | |
|---|---|
| pyridine:HF (30%:70%) | 0.3% |
| sulfolane | 9.7% |
| NMP | 90.0% |

Formulation B

| | |
|---|---|
| pyridine:HF (30%:70%) | 0.3% |
| sulfolane | 9.7% |
| DMSO | 90.0% |

Formulation C

| | |
|---|---|
| pyridine:HF (30%:70%) | 0.6% |
| sulfolane | 9.7% |
| DMSO | 89.7% |

Formulation D

| | |
|---|---|
| Methanol | 99.7% |
| triethylamine trihydrofluoride | 0.14% |
| boric acid | 0.05% |

Formulation E

| | |
|---|---|
| Methanol | 94.4% |
| triethylamine trihydrofluoride | 0.68% |
| boric acid | 0.21% |
| tert-butyl hydroperoxide | 4.7% |

Formulation F

| | |
|---|---|
| propylene glycol:HF (anhydrous 96:4) | 25% |
| methanol | 75% |

Formulation G

| | |
|---|---|
| propylene glycol:HF (anhydrous 96:4) | 25% |
| pentanol | 75% |

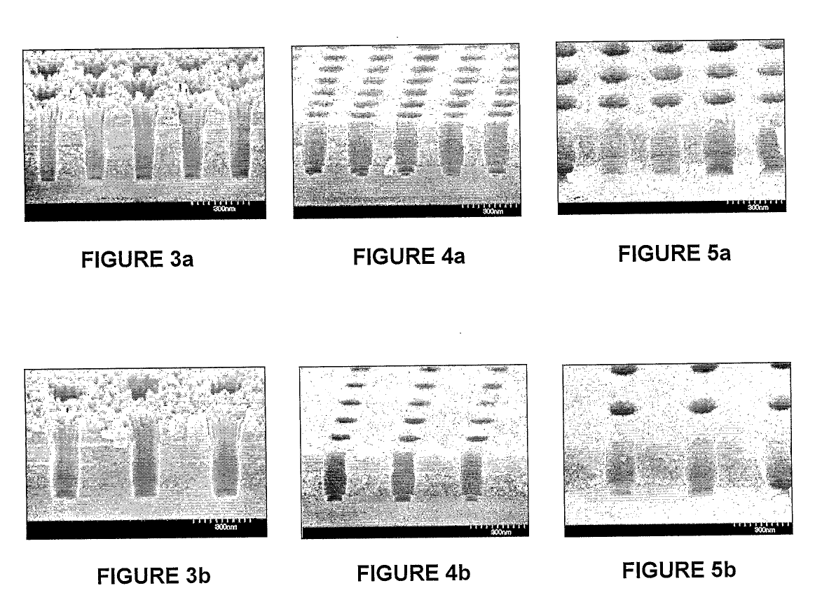

A patterned wafer including a 115 nm thick highly cross-linked hardened PMMA photoresist/acrylate-based BARC layer layer, a 105 nm thick SiO₂ layer, a 175 nm methyl silsesquioxane (MSQ) low-k material layer, and a silicon carbide etch stop (top to bottom in that order) was cleaned using the Formulation A, B, F and G concentrates, both with and without the dense fluid. Notably, XPS of the PMMA crust revealed that there is approximately 24.5% fluoropolymer incorporated therein. Field emission scanning electron microscope (FESEM) images were obtained using a Hitachi S4700. Two micrographs of the wafers before cleaning with formulations are illustrated in FIGS. 3a and 3b.

The conditions of the wet-clean using the concentrate may include a static soak at temperatures in a range from about 30° C. to about 70° C., preferably about 55° C. to about 65° C., for about 15 to about 45 minutes, preferably about 30 minutes. The conditions of the dense fluid clean, wherein supercritical CO₂ (SCCO₂) is the preferred dense fluid, may include a dynamic soak at temperatures in a range from about 30° C. to about 80° C., preferably about 65° C., for about 15 to about 45 minutes, preferably about 30 minutes.

The FESEM of the wafer of FIGS. 3a and 3b, having hardened highly cross-linked photoresist, post-etch residue, and BARC material thereon, following a wet-clean at 65° C. for 30 minutes using formulations A and B is shown in FIGS. 4a/4b and 5a/5b, respectively. Importantly, at least 99% of the photoresist material was removed using a wet-clean composition including either formulation A or B.

It was determined that DMSO and NMP were very important in the formulations for optimal cleaning efficiency. Although not wishing to be bound by theory, it is thought that the mechanism of highly cross-linked photoresist/crust/BARC removal is an undercutting process whereby the fluoride etchant penetrates into the highly cross-linked photoresist/crust/BARC and SiO₂ interface and slightly etches the interfacial region.

Similar to Formulations A and B, formulations F and G substantially removed the highly cross-linked photoresist/crust/BARC materials from the surface of the wafer.

### EXAMPLE 3

Dense fluid removal concentrates H and I were prepared as followed, wherein each component is present in weight percent, based on the total weight of the composition.

Formulation H

| | |
|---|---|
| sulfolane/HF:pyridine (1:1) | 3.3% |
| acetic acid | 85.0% |
| sulfolane | 11.7% |

Formulation I

| | |
|---|---|
| concentrated H₂SO₄ | 5.0% |
| acetic acid | 62.0% |
| sulfolane | 33.0% |

Sulfolane/pyridine:HF was prepared by combining 0.1 g of pyridine:HF (1:1) and 20 g of sulfolane in a 125 mL Nalgene™ bottle to form a 0.5 wt. % pyridine:HF (1:1) solution. The solution was stirred for 2 min prior to use.

Approximately 30 mL of formulation F was pumped (5 mL min-⁻¹ for 6 minutes) into a 100 mL CO₂ cleaning chamber containing the patterned wafer described in Example 2, and the wafer was processed in SCCO₂ at 35° C. and 220 bar for 15 min. After 15 minutes of stirring at 960 rpm, the wafer chamber was rapidly depressurized. The wafer was rinsed with methanol and isopropyl alcohol and dried under nitrogen gas. Experiments were repeated five times to ensure reproducibility.

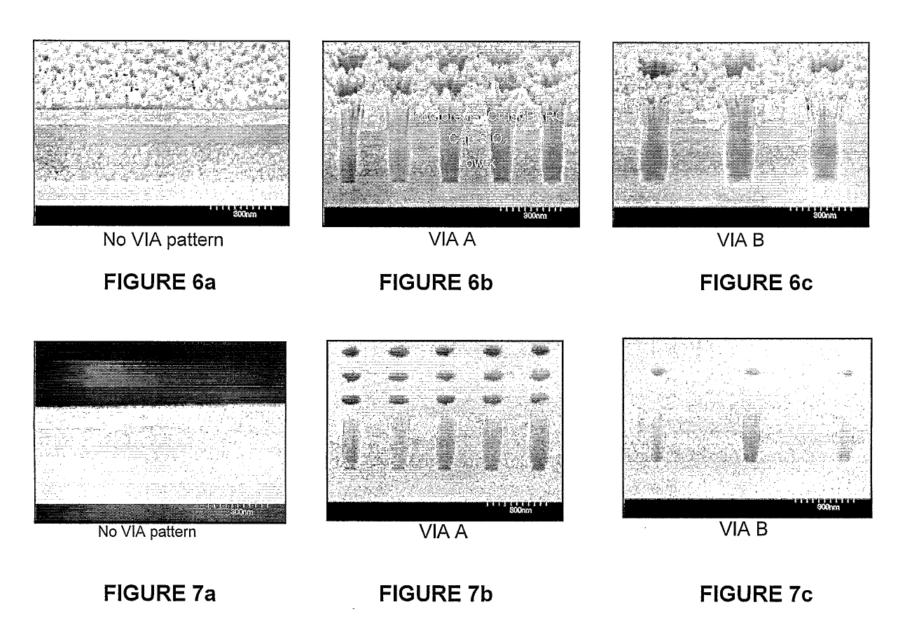

FESEM's of the wafers to be processed are shown in FIGS. 6a-6c, including the “no VIA” patterned region (FIG. 6a) and two different VIA structure regions (FIGS. 6b and 6c). As defined herein, the “no VIA” region corresponds to some portion of a patterned wafer wherein no etched vias or lines are present within about 5 μm to about 10 μm and as such, although the photoresist is hardened, the hardening is not as substantial as that in regions where VIAS and lines are prevalent.

It was determined that formulation H in SCCO₂ (35° C.; 15 min; 220 bar) removes the photoresist/crust/BARC in the non-patterned region and the “no VIA” patterned region and the VIA regions and porous MSQ layers were not severely etched. The mechanism of removal using formulation H is thought to be an undercutting process.

Thereafter, the wafer processed with formulation H was further processed in a second step with 30 mL of formulation I into a 100 mL chamber including SCCO₂ at 55° C. and 220 bar for 30 min. After 30 min of stirring at 960 rpm, the wafer chamber was rapidly depressurized, and the wafer rinsed with methanol and isopropyl alcohol and dried under nitrogen gas. Experiments were repeated five times to ensure reproducibility.

It was determined that the two step process including the exposure to formulation H followed by formulation I in SCCO₂ (55° C.; 30 min; 220 bar) removes 100% of the photoresist/crust/BARC in the non-patterned region and 85-90% of the photoresist/crust/BARC in the patterned region, as demonstrated by optical microscopy and FESEM (see FIGS. 7a-7c, which are FESEM's of the wafers of FIGS. 6a-6c, respectively, following the two-step process). The remaining heterogeneously distributed photoresist/crust/BARC layers are reduced by 55%. Some crust residue remains, however, the VIA regions and porous MSQ layers were not severely etched by the two-step process including formulation H and formulation I.

The mechanism of photoresist/crust/BARC removal with formulation I in SCCO₂ is likely an etching (dissolution) process, as evidenced by the 55% reduction of the photoresist/crust/BARC layers. The sulfuric acid dissolves the underlying bulk PMMA and BARC, which were not hardened during the reactive ion etching (RIE) process. Rapid depressurization at the end of the process is also proposed to aid in photoresist/crust/BARC removal. It is believed that this depressurization contributes to the heterogeneous crust removal.

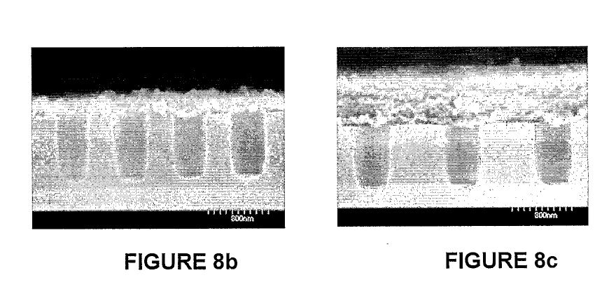

Formulation I in SCCO₂ may also be used to clean the wafers in a one-step cleaning process. Similar cleaning efficiency with respect to the two-step cleaning process is observed (i.e., 100% removal of the photoresist/crust/BARC in the non-patterned region and 80-90% removal of the photoresist/crust/BARC in the patterned region—see FIGS. 8b and 8c, which are FESEM's of the wafers of FIGS. 6b and 6c, respectively, following processing using just Formulation I), however, 20-30% of the photoresist/crust/BARC in the “no VIA” patterned region remained. The remaining heterogeneously distributed photoresist/crust/BARC layers are reduced by 55%, and primarily crust remains (see FIG. 8b). It should be noted that adding HF:pyridine (1:1) to formulation I in SCCO₂did not enhance the wafer cleaning.

It is noted that the wafers were processed separately using formulations H and H as wet-cleans, i.e., no SCCO₂, and it was determined that Formulations H and I work better when included with SCCO₂.

Accordingly, while the invention has been described herein in reference to specific aspects, features and illustrative embodiments of the invention, it will be appreciated that the utility of the invention is not thus limited, but rather extends to and encompasses numerous other aspects, features and embodiments. Accordingly, the claims hereafter set forth are intended to be correspondingly broadly construed, as including all such aspects, features and embodiments, within their spirit and scope.

1. A dense fluid concentrate comprising at least one co-solvent, optionally at least one oxidizer/radical source, optionally at least one surfactant, and optionally at least one silicon-containing layer passivating agent, wherein said concentrate is further characterized by comprising at least one of the following components (I) or (II):
(I) at least one fluoride source and optionally at least one acid; and
(II) at least one acid,
wherein said dense fluid concentrate is useful for removing hardened photoresist, post-etch residue and/or bottom anti-reflective coating (BARC) from a microelectronic device having said photoresist, residue and/or BARC thereon.

2. The concentrate of claim 1, comprising component (I), wherein the fluoride source comprises a HF complex selected from the group consisting of pyridine:HF complex, triethanolamine:HF complex, ethylene glycol:HF (anhydrous), propylene glycol:HF (anhydrous), triethylamine trihydrogen fluoride, and combinations thereof.

3. The concentrate of claim 1, comprising component (II), wherein the acid comprises a species selected from the group consisting of oxalic acid, succinic acid, citric acid, lactic acid, acetic acid, trifluoroacetic acid, formic acid, fumaric acid, acrylic acid, malonic acid, maleic acid, malic acid, L-tartaric acid, methyl sulfonic acid, trifluoromethanesulfonic acid, iodic acid, mercaptoacetic acid, thioacetic acid, glycolic acid, sulfuric acid, nitric acid, pyrrole, isoxazole, propynoic acid, pyrazine, pyruvic acid, acetoacetic acid, 1,1,1,5,5,5-hexafluoro-2,4-pentanedione (hfacH), 1,1,1-trifluoro-2,4-pentanedione (tfacH), acetylacetone (acacH), and mixtures thereof.

4. The concentrate of claim 1, comprising component (II), wherein the acid comprises a species selected from the group consisting of acetic acid, sulfuric acid, and combinations thereof.

5. (canceled)

6. The concentrate of claim 1, comprising component (I), with the provision that the co-solvent comprises sulfolane.

7. The concentrate of claim 1, comprising component (II), with the provision that the acid comprises sulfuric acid.

8. The concentrate of claim 1, wherein the co-solvent comprises at least one solvent selected from the group consisting of methanol, ethanol, isopropanol, N-methyl-pyrrolidinone (NMP), N-octyl-pyrrolidinone, N-phenyl-pyrrolidinone, dimethylsulfoxide (DMSO), sulfolane, catechol, ethyl lactate, acetone, ethyl acetate, butyl carbitol, monoethanolamine, butyrol lactone, diglycol amine, γ-butyrolactone, tetrahydrofuran (THF), dimethylformamide (DMF), methyl formate, diethyl ether, ethyl benzoate, acetonitrile, ethylene glycol, dioxane, methyl carbitol, monoethanolamine, pyridine, propylene carbonate, toluene, decane, hexane, hexanes, xylenes, odorless mineral spirits (petroleum naphtha), mineral spirits (hydrotreated heavy naphtha), cyclohexane, 1H,1H,9H-perfluoro-1-nonanol, perfluoro-1,2-dimethylcyclobutane, perfluoro-1,2-dimethylcyclohexane, perfluorohexane(s), and mixtures thereof.

9. (canceled)

10. The concentrate of claim 1, comprising the oxidizer/radical source, wherein the oxidizer/radical source comprises a species selected from the group consisting of alkyl peroxide (RO—OR), hydroperoxide (HO—OR), hydrogen peroxide, alkyl peracid (R-(C=O)—O—OH), alkoyl peroxide (R-(C=O)—O—O—(C=O)-R), alkyl hypochlorite (RO—Cl), wherein each R in the aforementioned R-substituted species is independently selected from straight chained and branched C₁-C₈ alkyl and substituted and unsubstituted C₆-C₁₀ aryl, sulfur trioxide (SO₃), nitric oxide (NO₂), ozone, 4,4-azobis(4-cyanovaleric acid), 1,1′-azobis(cyclohexanecarbonitrile), 2,2′-azobisisobutyronitrile (AIBN), tris(trimethylsilyl)silane (TTMSS), tetraethylthiuram disulfide, benzoyl peroxide, ethyl peroxydicarbonate, tert-butyl peracetate, di-tert-butyl peroxide, 2,4-pentanedione peroxide, 2-butanone peroxide, di-tert-amyl peroxide, tert-butylperoxy isopropyl carbonate, diacylperoxides, peroxydicarbonates, dialkyl peroxydicarbonates, acetyl peroxide, lauryl peroxide, cumene hydroperoxide, dicumyl peroxide, tert-butyl hydroperoxide, bis(trifluoroacetyl) peroxide, bis(2,3,3,3-tetrafluoro-2-(heptafluoropropoxy)-1-oxopropyl) peroxide, diacetyl peroxide, cyclohexanone peroxide, aryl halides, acyl halides, alkyl halides (e.g., ethylbromide and ethyliodide), halogens (e.g., chlorine and bromine), 2,2,6,6-tetramethylpiperidinoxyl (TEMPO), a source of ultraviolet (UV) light, a metal (e.g., copper, magnesium, zinc), and mixtures thereof.

11. The concentrate of claim 1, comprising the silicon-containing layer passivating agent, wherein the passivating agent comprises a species selected from the group consisting of: hexamethyldisilazane (HMDS); alkoxysilanes including (RO)₃SiX, (RO)₂SiX₂, (RO)SiX₃, where X=methyl, ethyl, propyl, butyl, and RO=methoxy, ethoxy, propoxy, butoxy; alkylhalosilanes including (R)₃SiX, (R)₂SiX₂, (R)SiX₃, where X=F, Cl, Br, I, and R=methyl, ethyl, propyl, butyl; boric acid; triethyl borate; 3-hydroxy-2-naphthoic acid; malonic acid; iminodiacetic acid; triethanolamine; and combinations thereof.

12. The concentrate of claim 1, comprising the surfactant.

13. (canceled)

14. A dense fluid removal composition comprising dense fluid and the dense fluid concentrate of claim 1.

15. The dense fluid composition of claim 14, wherein the dense fluid comprises carbon dioxide.

16. The concentrate of claim 1, further comprising residue material, wherein said residue comprises material selected from the group consisting of hardened photoresist material, post-etch residue materials, BARC materials, and combinations thereof.

17. The dense fluid composition of claim 15, further comprising residue material, wherein said residue comprises material selected from the group consisting of hardened photoresist material, post-etch residue materials, BARC materials, and combinations thereof.

18. (canceled)

19. The concentrate of claim 1, selected from the group consisting of Formulations A-I, wherein all percentages are by weight, based on the total weight of the formulation:
Formulation A
pyridine:HF (30%:70%) 0.3%
sulfolane 9.7%
NMP 90.0%
Formulation B
pyridine:HF (30%:70%) 0.3%
sulfolane 9.7%
DMSO 90.0%
Formulation C
pyridine:HF (30%:70%) 0.6%
sulfolane 9.7%
DMSO 89.7%
Formulation D
Methanol 99.7%
triethylamine trihydrofluoride 0.14%
boric acid 0.05%
Formulation E
Methanol 94.4%
triethylamine trihydrofluoride 0.68%
boric acid 0.21%
tert-butyl hydroperoxide 4.7%
Formulation F
propylene glycol:HF (anhydrous 96:4) 25%
methanol 75%
Formulation G
propylene glycol:HF (anhydrous 96:4) 25%
pentanol 75%
Formulation H
sulfolane/HF:pyridine (1:1) 3.3%
acetic acid 85.0%
sulfolane 11.7%
Formulation I
concentrated H₂SO₄ 5.0%
acetic acid 62.0%
sulfolane 33.0%.

20. A kit comprising, in one or more containers, one or more of the following reagents for forming a dense fluid concentrate, wherein said concentrate comprises comprising at least one co-solvent, optionally at least one oxidizer/radical source, optionally at least one surfactant, and optionally at least one silicon-containing layer passivating agent, wherein said concentrate is further characterized by comprising at least one of the following components (I) or (II):
(I) at least one fluoride source and optionally at least one acid; and
(II) at least one acid,
and wherein the kit is adapted to form dense fluid concentrates suitable for removing hardened photoresist, post-etch residue and/or bottom anti-reflective coating (BARC) from a microelectronic device having said photoresist, residue and/or BARC thereon.

21. A method of removing hardened photoresist, post-etch residue and/or bottom anti-reflective coating (BARC) from a microelectronic device having same thereon, said method comprising contacting the microelectronic device with a dense fluid concentrate for sufficient time and under sufficient contacting conditions to at least partially remove said hardened photoresist, post-etch residue and/or BARC from the microelectronic device having said photoresist, residue and/or BARC thereon, wherein the dense fluid concentrate comprises at least one co-solvent, optionally at least one oxidizer/radical source, optionally at least one surfactant, and optionally at least one silicon-containing layer passivating agent, wherein said concentrate is further characterized by comprising at least one of the following components (I) or (II):
(I) at least one fluoride source and optionally at least one acid; and
(II) at least one acid.

22. The method of claim 21, wherein said contacting comprises at least one condition selected from the group consisting of: time in a range of from about 5 minutes to about 45 minutes, temperature in a range from about 30° C. to about 80° C.; and combinations thereof.

23. (canceled)

24. The method of claim 21, co-solvent comprises at least one solvent selected from the group consisting of methanol, ethanol, isopropanol, N-methyl-pyrrolidinone (NMP), N-octyl-pyrrolidinone, N-phenyl-pyrrolidinone, dimethylsulfoxide (DMSO), sulfolane, catechol, ethyl lactate, acetone, ethyl acetate, butyl carbitol, monoethanolamine, butyrol lactone, diglycol amine, γ-butyrolactone, tetrahydrofuran (THF), dimethylformamide (DMF), methyl formate, diethyl ether, ethyl benzoate, acetonitrile, ethylene glycol, dioxane, methyl carbitol, monoethanolamine, pyridine, propylene carbonate, toluene, decane, hexane, hexanes, xylenes, odorless mineral spirits (petroleum naphtha), mineral spirits (hydrotreated heavy naphtha), cyclohexane, 1H,1H,9H-perfluoro-1-nonanol, perfluoro-1,2-dimethylcyclobutane, perfluoro-1,2-dimethylcyclohexane, perfluorohexane(s), and mixtures thereof;
wherein the fluoride source comprises a HF complex selected from the group consisting of pyridine:HF complex, triethanolamine:HF complex, ethylene glycol:HF (anhydrous), propylene glycol:HF (anhydrous), triethylamine trihydrogen fluoride, and combinations thereof; and
wherein the acid comprises a species selected from the group consisting of oxalic acid, succinic acid, citric acid, lactic acid, acetic acid, trifluoroacetic acid, formic acid, fumaric acid, acrylic acid, malonic acid, maleic acid, malic acid, L-tartaric acid, methyl sulfonic acid, trifluoromethanesulfonic acid, iodic acid, mercaptoacetic acid, thioacetic acid, glycolic acid, sulfuric acid, nitric acid, pyrrole, isoxazole, propynoic acid, pyrazine, pyruvic acid, acetoacetic acid, 1,1,1,5,5,5-hexafluoro-2,4-pentanedione (hfacH), 1,1,1-trifluoro-2,4-pentanedione (tfacH), acetylacetone (acacH), and mixtures thereof.

25. (canceled)

26. (canceled)

27. A method of removing hardened photoresist, post-etch residue and/or bottom anti-reflective coating (BARC) from a microelectronic device having same thereon, said method comprising contacting the microelectronic device with a dense fluid composition for sufficient time and under sufficient contacting conditions to at least partially remove said hardened photoresist, post-etch residue and/or BARC from the microelectronic device having said photoresist, residue and/or BARC thereon, wherein the dense fluid composition comprises at least dense fluid and the dense fluid concentrate of claim 1.

28. The method of claim 27, wherein the dense fluid comprises a fluid selected from the group consisting of a supercritical fluid and a subcritical fluid.

29. The method of claim 27, wherein the dense fluid comprises carbon dioxide.

30. The method of claim 27, wherein the contacting comprises conditions selected from the group consisting of: pressure in a range of from about 1500 to about 4500 psi; temperature in a range from about 30° C. to about 80° C.; and combinations thereof.

31-35. (canceled)
